(19) United States
(12) Patent Application Publication
(10) Pub. No.: US 2022/0035737 A1
(43) Pub. Date: Feb. 3, 2022

(54) STORAGE APPARATUS, HIGH DIMENSIONAL GAUSSIAN FILTERING CIRCUIT, STEREO DEPTH CALCULATION CIRCUIT, AND INFORMATION PROCESSING APPARATUS

(71) Applicant: SONY CORPORATION, TOKYO (JP)

(72) Inventor: KAZUNORI YASUDA, TOKYO (JP)

(21) Appl. No.: 17/276,542

(22) PCT Filed: Jun. 13, 2019
(86) PCT No.: PCT/JP2019/023427

§ 371 Date: Mar. 16, 2021

(30) Foreign Application Priority Data
Sep. 27, 2018 (JP) 2018-181376

(51) Int. Cl. G06F 12/06; H03H 17/02

(52) U.S. Cl. CPC G06F 12/06; G06F 2212/1008; H03H 17/0282

(57) ABSTRACT

A storage apparatus of an associative array type that stores a large-sized value at a low cost is provided. The storage apparatus of the associative array type includes a first memory, a second memory that stores a value, and a third memory. The first memory stores a key and an address of the second memory. The address of the second memory is an address where the value corresponding to the key is stored. The third memory stores an address of the first memory. The address of the first memory is an address where the key corresponding to the value stored in the second memory is stored. The first memory further stores a flag that indicates whether or not the key has been registered.

### TECHNICAL FIELD

A technology disclosed in the present description relates to a storage apparatus of an associative array type, a high dimensional gaussian filtering circuit, a stereo depth calculation circuit, and an information processing apparatus.

### BACKGROUND ART

In the relevant industry, there has been known an associative array system which pairs a key (Key) and a value (Value) and manages these (for example, see PTL 1). The key corresponds to an address in an address space such as a memory, while the value corresponds data stored at the address. Normally, the value is stored in association with the original key at an address corresponding to a hash value as a converted value of the original key by a hash function. The address address having a large bit length is compressed into the hash value having a small bit length. Accordingly, an associative array is considered to be effective for reliably producing the address space which may become a considerably large space if handled only in a simple manner.

A “collision” where multiple different keys are converted into an identical hash value occurs in some cases. An open addressing method and a chain method have been known as processing for handling the collision in the associative array system. The open addressing method is a method for searching another address available at the time of a collision. On the other hand, the chain method is a method for connecting keys causing a collision, by using a pointer.

### CITATION LIST

### Patent Literature

### [PTL 1]

Japanese Patent Laid-open No. 2001-67881

### Non Patent Literature

[NPL 1]

Andrew Adams et al., “Fast High-Dimensional Filtering Using the Permutohedral Lattice” (Eurographics 2010 Runner up for Best Paper)

### SUMMARY

### Technical Problem

An object of a technology disclosed in the present description is to provide a storage apparatus of an associative array type, a high dimensional gaussian filtering circuit, a stereo depth calculation circuit, and an information processing apparatus.

### Solution to Problem

A first aspect of the technology disclosed in the present description is directed to a storage apparatus of an associative array type including a first memory, a second memory that stores a value, and a third memory. The first memory stores a key and an address of the second memory, the address of the second memory being an address where the value corresponding to the key is stored. The third memory stores an address of the first memory, the address of the first memory being an address where the key corresponding to the value stored in the second memory is stored.

The first memory further stores a flag that indicates whether or not the key has been registered.

Further, the storage apparatus according to the first aspect calculates the address at which the key is stored in the first memory, from the key with use of a hash function, and calculates the address at which the key is stored in the first memory, by using an open addressing method at the time of a collision.

Further, a second aspect of the technology disclosed in the present description is directed to a high dimensional gaussian filtering (HDGF) circuit configured to store a calculation value by using the storage apparatus according to the first aspect.

In addition, a third aspect of the technology disclosed in the present description is directed to a stereo depth calculation circuit that performs a depth calculation by using the HDGF circuit according to the second aspect.

Besides, a fourth aspect of the technology disclosed in the present description is directed to an information processing apparatus that stores data by an associative array system with use of the storage apparatus according to the first aspect.

### Advantageous Effect of Invention

Provided according to the technology disclosed in the present description are a storage apparatus of an associative array type, a high dimensional gaussian filtering circuit, a stereo depth calculation circuit, and an information processing apparatus, each capable of storing a large-sized value at a low cost.

Note that advantageous effects described in the present description are presented only by way of example and that advantageous effects produced by the present invention are not limited to these effects. In addition, the present invention may further offer additional advantageous effects as well as the advantageous effect described above.

Other objects, features and advantages of the technology disclosed in the present description will become apparent on the basis of more detailed description presented in conjunction with an embodiment described below and accompanying drawings.

### BRIEF DESCRIPTION OF DRAWINGS

FIG. 1 is a diagram depicting a hardware configuration example of a storage apparatus 100 of an associative array type.

FIG. 2 is a flowchart presenting a processing procedure for initializing the storage apparatus 100.

FIG. 3 is a flowchart presenting a processing procedure for key search performed by the storage apparatus 100.

FIG. 4 is a flowchart presenting a processing procedure for value reading based on key search performed by the storage apparatus 100.

FIG. 5 is a flowchart presenting a processing procedure for value writing based on key search performed by the storage apparatus 100.

FIG. 6 is a flowchart presenting a processing procedure for new key and value writing performed by the storage apparatus 100.

FIG. 7 is a flowchart presenting a processing procedure for sequential all key and value reading performed by the storage apparatus 100.

FIG. 8 is a flowchart presenting a processing procedure for sequential all key and value reading and value update performed by the storage apparatus 100.

FIG. 9 depicts an example of a pipeline circuit where a processing procedure performed at the time of key search is implemented using a clocked SRAM.

FIG. 10 is a diagram presenting a timing chart of the pipeline circuit depicted in FIG. 9.

### DESCRIPTION OF EMBODIMENT

An embodiment of the technology disclosed in the present description will hereinafter be described in detail with reference to the drawings.

### A. Application Example of HDGF

For example, image processing using a high dimensional gaussian filtering (HDGF) technology, which is a technology continuously developed in recent years, considerably increases a computing volume and requires a sufficiently large address space. For example, the HDGF technology here is capable of smoothly performing noise removal from a two-dimensional image and a three-dimensional CT (Computed Tomography) image, region division by semantic segmentation, and others. The HDGF technology requires a large address space so as to handle, as five to six-dimensional values, not only pixel values but also pixel values including coordinate values or values separately calculated, in a case of input of a two-dimensional image, for example.

The present applicant considers that introduction of an associative array system is appropriate for management of data used for image processing which uses the HDGF technology. HDGF does not require order management.

Meanwhile, examples of a method for implementing an associative array using hash include an open addressing method and a chain method (described above). Assuming that image processing of a conditional random field system such as HDGF is operated in real time with low power consumption, implementation of a pipeline processing circuit provided by hardware is required. In this case, the present applicant considers that the open addressing method capable of speculatively generating addresses is more suited for achieving sequential synonym determination of keys.

Reduction of hash collisions is effective here to maximize pipeline throughput. For achieving this reduction, a large, post-hash address space needs to be produced. This necessity increases hardware cost.

The HDGF technology applied to a stereo depth calculation process will now be discussed.

In a typical stereo depth calculation process using a correlation between a left-eye image and a right-eye image, a similarity cost (cost) at the time of a shift of the left-eye image and the right-eye image by a disparity value (disparity) is calculated for plural disparity candidates. Accordingly, plural values are calculated for one pixel value in the left-eye image or the right-eye image. A calculation value for each pixel value will be referred to as a (one-dimensional) cost vector. In addition, an image itself is constituted by two-dimensional data. Accordingly, the entire cost has a three-dimensional data structure. This data structure is normally called a cost volume.

For example, in a case of search for 96 disparity candidates for a VGA (Video Graphics Array) image (640×480 pixels), the cost volume has a volume of 117 megabytes for a cost size set to a float type (4 bytes). This volume is normally a volume to be stored not in an SRAM (Static Random Access Memory) but a DRAM (Dynamic RAM).

Characteristics of the cost volume differ for each characteristic of an object, such as the presence or absence of patterns of an original image. An algorithm for selecting an optimum disparity from plural disparity candidates has already been studied in a continuous manner, and a large number of systems such as SGM (Semi Global Matching) have been proposed.

In a case where the HDGF technology is applied to a stereo depth calculation process, a large-sized cost volume is recorded in value data of an associative array. As described above, hardware cost increases when a sufficiently large, post-hash address space is produced to reduce hash collisions. In a case where a value paired with a key is managed in an associative array, a memory capacity for values increases by an increase in the address space. Accordingly, a problem of an extremely increased hardware cost may arise.

Accordingly, proposed hereinafter in the present description will be a storage apparatus of an associative array type capable of reducing entire hardware cost by efficiently storing large-sized value data while securing a large address space to reduce hash collisions.

### B. Cost Volume Calculation Procedure to Which HDGF is Applied

Explained here will be a calculation procedure performed in a case where HDFG is applied to a cost volume in a stereo depth calculation process (see NPL 1). This calculation procedure achieves a filtering process by repeating three steps of database creation, execution of filtering, and reconfiguration of cost volume. The respective steps will hereinafter be described.

B-1. Database Creation

In a step for registering keys and values in an associative array, a database is searched for pixels at all coordinates (H, V) (where, H: horizontal coordinate, V: vertical coordinate) in an original image by using a key (Key) generated from an RGB value of the pixel at the corresponding coordinates and the coordinates (H, V) in the original image by a predetermined calculation formula (hash function). Subsequently, a cost vector of the pixel is newly registered in the database when no registration corresponding to the key is found in the database. In addition, in a case where registration corresponding to the key is already included in the database, the key is added to the searched cost vector (calcSplat).

B-2. Execution of Filtering

Different two keys are generated on the basis of the key value for each of all values within the associative array, and gaussian filter (1:2:1) calculation is performed using the associated two values and the corresponding value to update the corresponding value (calcBlur).

B-3. Reconfiguration of Cost Volume

The database is searched using a key generated by the same calculation formula as that used for the database creation of B-1 described above, and a value thus obtained is stored in the cost volume as a predetermined cost vector (calcSlice).

### C. Functions Necessary for Associative Array

Functions that are necessary for an associative array and that are used for the calculation procedure constituted by the three steps of database creation, execution of filtering, and cost volume reconfiguration described in Section B described above are the following functions (1) to (7). However, note that an operation for individually deleting data from the database is not used in the present embodiment.

### (1) Initialization

(2) Key search
(3) Value reading by key search
(4) Value writing by key search
(5) New key and value writing
(6) Sequential all key and value reading
(7) Sequential all key and value reading and value update

### D. Storage Apparatus of Associative Array Type

A storage apparatus of an associative array type according to the present embodiment will be specifically described here. This storage apparatus is capable of reducing entire hardware cost by efficiently storing large-sized value data while securing a large address space to reduce hash collisions.

D-1. Hardware Configuration of Storage Apparatus of Associative Array Type

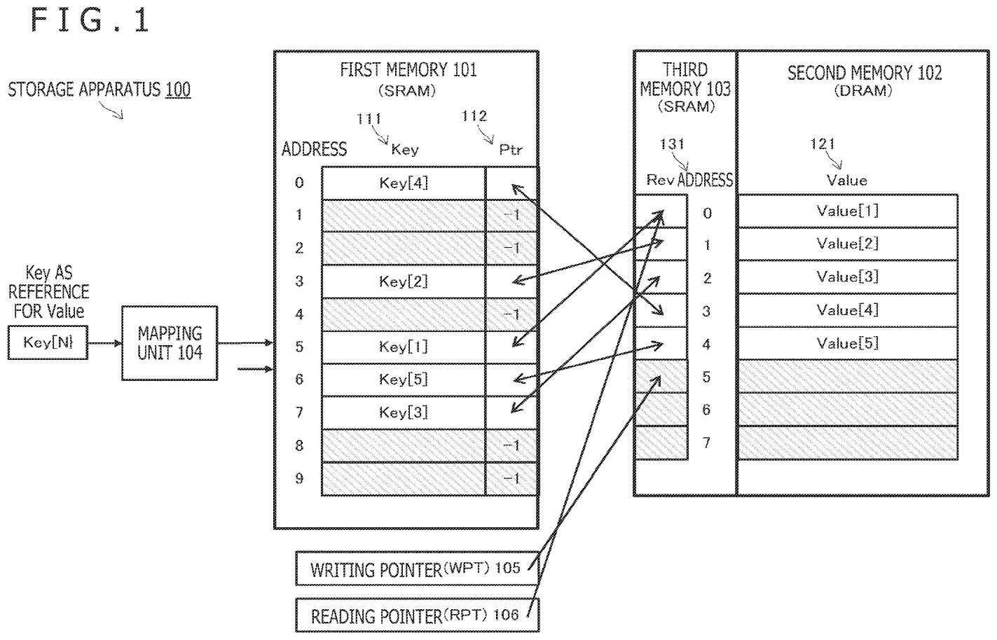

FIG. 1 depicts a hardware configuration example of a storage apparatus 100 of an associative array type according to the present embodiment. The storage apparatus 100 includes a first memory 101, a second memory 102, and a third memory 103, and is configured to store keys and values in association with each other.

The first memory 101 includes a key region 111 for storing keys and a pointer (Ptr) region 112 for storing storage places of values corresponding to keys. A key is stored at an address of the first memory 101 which is an address indicated by a hash value generated by conversion of the key with use of a hash function. In addition, a value corresponding to the key is stored in the second memory 102 separately from the key. Specifically, stored at each of addresses in the pointer region 112 is an address of the second memory 102 where a value corresponding to a key stored in the key region 111 at the same address as the address of the pointer region 112 is stored. Moreover, −1 is stored in the pointer region 112 at an unused address in the first memory 101 to indicate that no effective key is present at the corresponding address of the key region 111. Accordingly, the pointer region 112 also functions as a “flag” indicating whether or not each of the addresses in the first memory 101 is unused. It is assumed that the first memory 101 includes an SRAM.

The second memory 102 includes a value region 121 for storing values. Each of values corresponding to keys stored at respective addresses of the key region 111 of the first memory 101 is stored at a corresponding address in the second memory 102 (or the value region 121) which is the same address as the address stored in the pointer region 112.

According to the present embodiment, the operation for individually deleting data from the database is not used. Accordingly, the second memory 102 is sequentially used in an order of registration from address 0. There is thus such a characteristic that addresses up to an address corresponding to the number smaller than the number of used addresses by one are used in the second memory 102, and that all addresses after the last address of the used part constitute an unused part of addresses.

The values are relatively large data. It is thus assumed that the second memory 102 includes a DRAM. Accordingly, in a case where the storage apparatus 100 of the associative array type is used for the cost volume calculation procedure to which HDGF described in the above Section B has been applied, an advantageous effect that the large cost volome is allowed to be stored in DRAM which has an inexpensive unit price per volume.

The third memory 103 includes a reverse pointer (Rev) region 131. Stored at each of addresses in the reverse pointer region 131 is an address of the first memory 101 where a key corresponding to a value stored at the same address as the address of the reverse pointer region 131 in the second memory 102 (or value region 121) is stored, i.e., a reverse pointer.

According to the present embodiment, the operation for individually deleting data from the database is not used. In this case, the third memory 103 is thus sequentially used in an order of registration from address 0 similarly to the second memory 102. Accordingly, addresses up to an address corresponding to the number smaller than the number of used addresses by one are used in the third memory 103, and all addresses after the last address of the used part correspond to an unused part. It is assumed that the third memory 103 includes an SRAM.

A mapping unit 104 has a function of mapping spaces of keys each having a large space at addresses in a space in the first memory 101. Specifically, the mapping unit 104 calculates addresses (candidate addresses) in the first memory 101 from an inquired key by using an ordinary hash function. Specifically, a hash value calculated from a key by using the hash function becomes an address at which the corresponding key is stored in the first memory 101.

A writing pointer (WPT) 105 indicates an address to which a value is next written in the second memory 102. Moreover, the writing pointer 105 also indicates the number of used addresses in each of the second memory 102 and the third memory 103. In the present embodiment, the operation for individually deleting data from the database is not used. Accordingly, the writing pointer 105 sequentially indicates an address for next writing in the value region 121 of the second memory 102 from the beginning address.

A reading pointer (PRT) 106 indicates an address of the second memory 102 from which a value is read. The reading pointer 106 is used when all keys and values are sequentially read out. Details of a processing procedure for the sequential all reading will be described later.

The writing pointer 105 and the reading pointer 106 may be disposed within an SRAM such as the first memory 101.

Note that FIG. 1 exemplifies a state after keys and values are written to the storage apparatus 100 in an initial state in an order of Key [1], Key [2], Key [3], Key [4], and Key [5]. In this figure, unused parts of the key region 111, the value region 121, and the reverse pointer region 131 are filled with diagonal lines.

First, at the time of writing a value of Key [1], the mapping unit 104 calculates a hash value “5” of Key [1] as a candidate address by using the hash function. Address 5 of the key region 111 of the first memory 101 is unused. Accordingly, Key [1] is stored, and a value of Value [1] corresponding to Key [1] is stored at address 0 of the value region 121 of the second memory 102. Moreover, address “0” where Value [1] of the value region 121 has been stored is stored at address 5 of the pointer region 112 of the first memory 101. In addition, address “5” in the first memory 101 where Key [1] corresponding to Value [1] has been stored is stored at address 0 of the reverse pointer region 131 of the third memory 103.

Next, at the time of writing a value of Key [2], the mapping unit 104 calculates a hash value “3” of Key [2] as a candidate address. Address 3 of the key region 111 is unused, and thus, Key [2] is stored at this address. In addition, a value of Value [2] corresponding to Key [2] is stored at address 1 of the value region 121, while address “1” at which Value [2] has been stored is stored at address 3 of the pointer region 112. Moreover, address “3” in the first memory 101 at which Key [2] corresponding to Value [2] has been stored is stored at address 1 of the reverse pointer region 131.

Concerning subsequent Key [3] and Key [4], address 7 and address 0 of the key region 111, which are addresses calculated as candidate addresses from respective keys by using the hash function, are also unused addresses. Accordingly, keys of Key [3] and Key [4] are sequentially stored at these addresses, and values of Value [3] and Value [4] corresponding to Key [3] and Key [4] are sequentially stored at address 2 and address 3 of the value region 121. Thereafter, address 2 and address 3 in the value region 121, which are addresses where the respective values have been stored, are stored at address 7 and address 0 in the pointer region 112, respectively. In addition, addresses “7” and “0” in the first memory 101, which are addresses where keys corresponding to the respective values have been stored, are stored at address 2 and address 3 in the reverse pointer region 131, respectively.

Furthermore, at the time of writing of a value corresponding to Key [5], address 5 of the key region 111 calculated as a candidate address for Key [5] by the mapping unit 104 has already been used by Key [1]. In other words, a hash collision is caused. This collision is thus avoided using the open addressing method. Specifically, address 6 of the key region 111 as an address obtained by incrementing the candidate address by only one is unused. Accordingly, Key [5] is stored at this address, and a value of Value [5] corresponding to Key [5] is stored at address 4 of the value region 121. Moreover, address “4” where Value [5] has been stored is stored at address 6 of the pointer region 112. In addition, address “6” in the first memory 101 where Key [5] corresponding to Value [5] has been stored is stored at address 4 of the reverse pointer region 131.

Note that details of key search and a writing operation performed by the storage apparatus 100 will be described in subsequent Section E.

### E. Operation of Storage Apparatus

Described here will be processing procedures for carrying out an operation for achieving the respective functions necessary for the associative array in the storage apparatus 100 depicted in FIG. 1.

E-1. Initialization

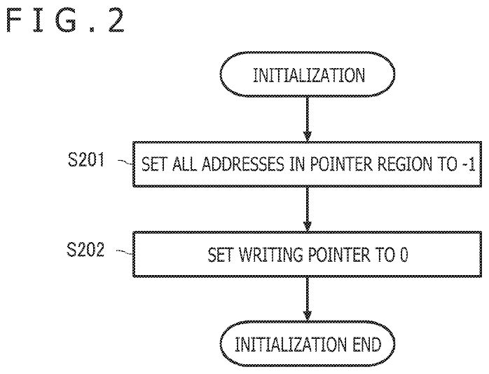

FIG. 2 presents a processing procedure for initializing the storage apparatus 100, in a form of a flowchart.

For indicating that all addresses in the first memory 101 are unused, “−1” is set for all the addresses in the pointer region 112 of the first memory 101 (step S201). Subsequently, “0” is set for the writing pointer 105 (step S202) to indicate that the beginning address of the second memory 102 is a writing position. Thereafter, the initialization process of the storage apparatus 100 ends.

E-2. Key Search

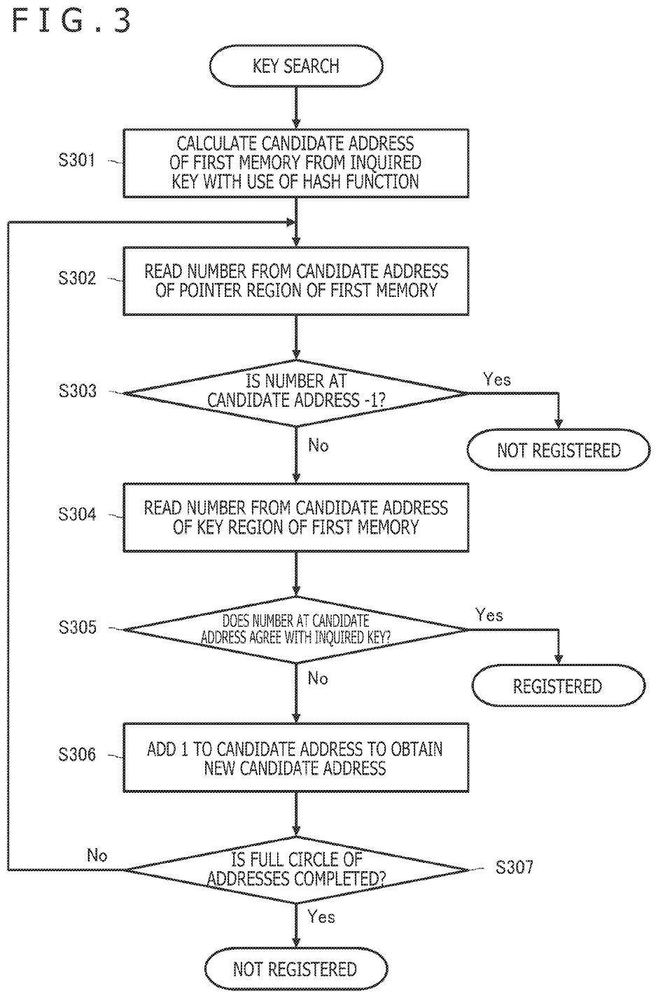

FIG. 3 presents a processing procedure for key search performed by the storage apparatus 100, in a form of a flowchart.

First, a key as a reference for a value is input to the mapping unit 104, and a candidate address of the first memory 101 is calculated using an ordinary hash function (step S301).

Next, a number is read from the candidate address of the pointer region 112 of the first memory 101 (step S302).

The pointer region 112 also functions as a “flag” indicating whether or not the respective addresses in the first memory 101 are unused. In this case, −1 is stored at each of unused addresses of the pointer region 112 (as described above). Accordingly, it is checked whether or not the number read from the candidate address in step S302 is −1 (step S303).

When the number read from the candidate address is −1 here (Yes in step S303), it is considered that the corresponding candidate address is unused and that the value is yet to be registered for the corresponding key. Accordingly, this process ends.

On the other hand, when the number read from the candidate address is not −1 (No in step S303), the corresponding candidate address is already used. Accordingly, an address matching the search key is searched in the key region 111.

As a process for search in the key region 111, a number is first read from a candidate address of the key region 111 of the first memory 101 (step S304). Then, it is checked whether or not the number read from the candidate address of the key region 111 of the first memory 101 agrees with the number input in step S301 as the key as the reference for the value (step S305).

Here, in a case where the number read from the candidate address of the key region 111 agrees with the key as the reference (Yes in step S305), it is considered that the key has been registered at the candidate address calculated from the key with use of the hash function. Accordingly, this process ends.

On the other hand, in a case where the number read from the candidate address of the key region 111 does not agree with the key as the reference (No in step S305), it is considered that a hash collision has been caused. Accordingly, the collision is avoided using the open addressing method. Specifically, the candidate address calculated in step S301 is incremented by only one to obtain a new candidate address (step S306).

It is checked here whether or not the new candidate address has turned full circle of the addresses in the first memory 101 (step S307). When full circle is not completed (No in step S307), the process returns to step S302 to check again whether or not the corresponding key has been stored at the new candidate address.

In addition, in a case where full circle of the addresses in the first memory 101 is completed (Yes in step S307), it is considered that an address matching the inquired key is absent. Accordingly, this process ends considering that the value is yet to be registered for the corresponding key.

For example, in a case where the storage apparatus 100 searches a key of Key [1] in a state where keys and values have already been registered as depicted in FIG. 1, the mapping unit 104 first calculates a hash value “5” of Key [1] as a candidate address by using the hash function (step S301). The number read from address 5 of the pointer region 112 of the first memory 101 is not −1 (No in step S302 and step S303), and thus, a number is next read from address 5 of the key region 111 of the first memory 101 (step S304). This number agrees with the searched key of Key [1] (Yes in step S305). Accordingly, a result that the searched key of Key [1] has been registered is returned, and this process ends. A result that the searched key has already been registered can also be obtained by a similar processing flow for each of keys of Key [2], Key [3], and Key [4].

On the other hand, in a case of search for a key of Key [5], the mapping unit 104 first calculates a hash value “5” of Key [1] as a candidate address by using the hash function (step S301). The number read from address 5 in the pointer region 112 of the first memory 101 is not −1 (No in step S302 and step S303), and thus, a number is next read from address 5 of the key region 111 of the first memory 101 (step S304). This number does not agree with the searched key of Key [5] (No in step S305). In other words, a hash collision is caused, and thus the collision is avoided using the open addressing method. Specifically, the candidate address is incremented by only one to obtain address 6 (step S306). Full circle of the addresses in the first memory 101 is yet to be completed (No in step S307), and thus, the flow returns to step S302 to repeatedly perform key search at address 6. Then, a number is read from address 6 of the key region 111 (step S304). This number agrees with the searched key of Key [5] (Yes in step S305). Accordingly, a result that the searched key of Key [5] has been registered is returned, and this process ends.

E-3. Value Reading by Key Search

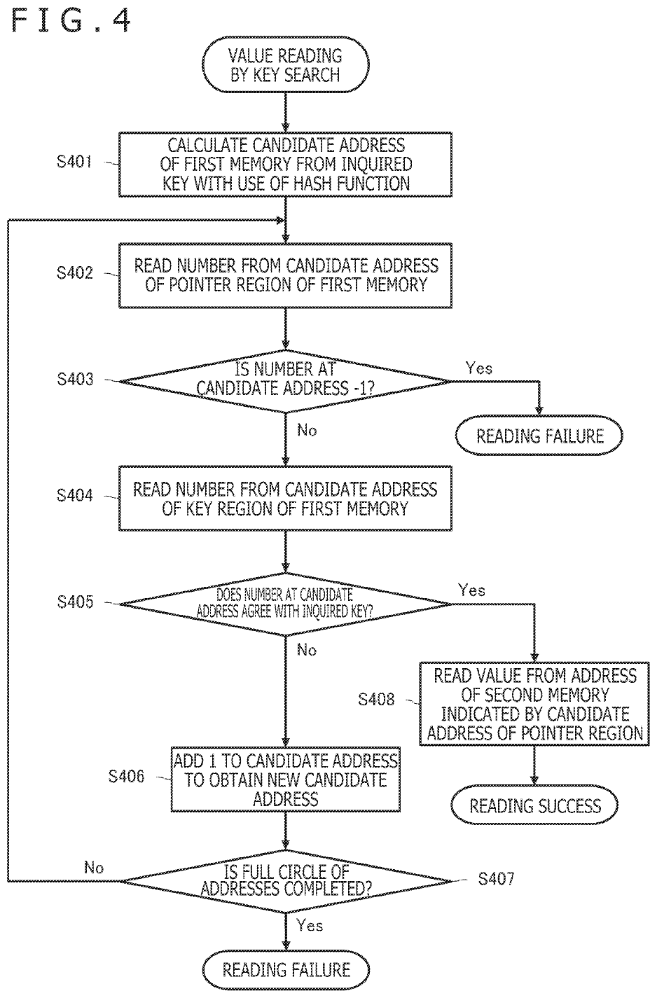

FIG. 4 presents a processing procedure for value reading based on key search performed by the storage apparatus 100, in a form of a flowchart.

First, a key corresponding to a value intended to be read is input to the mapping unit 104, and a candidate address of the first memory 101 is calculated using an ordinary hash function (step S401).

Next, a number is read from the candidate address of the pointer region 112 of the first memory 101 (step S402). Thereafter, it is checked whether or not the number read from the candidate address in step S402 is −1, i.e., whether or not the corresponding candidate address is unused (step S403).

When the number read from the candidate address is −1 here (Yes in step S403), it is considered that the corresponding address is unused and that the value is yet to be registered for the corresponding key. Accordingly, this process ends considering that value reading based on key search has failed.

On the other hand, when the number read from the candidate address is not −1 (No in step S403), the candidate address is already used. Accordingly, an address matching the searched key is searched in the key region 111.

As a process for search in the key region 111, a number is first read from a candidate address of the key region 111 of the first memory 101 (step S404). Next, it is checked whether or not the number read from the candidate address of the key region 111 of the first memory 101 agrees with the number input in step S401 as the key corresponding to the value intended to be read (step S405).

In a case where the number read from the candidate address of the key region 111 agrees with the key corresponding to the value intended to be read here (Yes in step S405), it is considered that the key has been registered at the candidate address calculated from the key with use of the hash function. Accordingly, a pointer value stored at the corresponding candidate address of the pointer region 112 of the first memory 101 is read out. Thereafter, a value is read from the address indicated by the pointer value in the second memory 102 (step S408), and this process ends.

On the other hand, in a case where the number read from the candidate address of the key region 111 does not agree with the key corresponding to the value intended to be read (No in step S405), it is considered that a hash collision has been caused. Accordingly, the collision is avoided using the open addressing method. Specifically, the candidate address calculated in step S401 is incremented by only one to obtain a new candidate address (step S406).

It is checked here whether or not the new candidate address has turned full circle of the addresses in the first memory 101 (step S407). When full circle is not completed (No in step S407), the process returns to step S402 to check again whether or not the corresponding key has been stored at the new candidate address.

On the other hand, in a case where full circle of the addresses in the first memory 101 is completed (Yes in step S407), an address matching the inquired key is absent. In this case, it is considered that the value is yet to be registered for the corresponding key. Accordingly, this process ends considering that value reading based on key search has failed.

For example, in a case where the storage apparatus 100 performs value reading based on search for a key of Key [1] in a state where keys and values have already been registered as depicted in FIG. 1, the mapping unit 104 first calculates a hash value “5” of Key [1] as a candidate address by using the hash function (step S401). The number read from address 5 of the pointer region 112 of the first memory 101 is not −1 (No in step S402 and step S403), and thus, a number is next read from address 5 of the key region 111 of the first memory 101 (step S404). This number agrees with the searched key of Key [1] (Yes in step S405). Accordingly, a value of Value [1] corresponding to Key [1] is read from address 0 of the second memory 102, which is an address indicated by a pointer value stored at address 5 of the pointer region 112 of the first memory 101 (step S408). Thereafter, this process ends. Values of Value [2], Value [3], and Value [4] corresponding to keys of Key [2], Key [3], and Key [4], respectively, can be read by a similar value reading processing flow based on key search.

On the other hand, in a case of value reading based on search for a key of Key [5], the mapping unit 104 first calculates a hash value “5” of Key [1] as a candidate address by using the hash function (step S401). The number read from address 5 of the pointer region 112 of the first memory 101 is not −1 (No in step S402 and step S403), and thus, a number is next read from address 5 of the key region 111 of the first memory 101 (step S404). This number does not agree with the searched key of Key [5] (No in step S405). In other words, a hash collision is caused, and thus, the collision is avoided using the open addressing method. Specifically, the candidate address is incremented by only one to obtain address 6 (step S406). Full circle of the addresses in the first memory 101 is yet to be completed (No in step S407), and thus, the flow returns to step S402 to repeatedly perform key search at address 6. Thereafter, a number is read from address 6 of the key region 111 (step S404). This number agrees with the searched key of Key [5] (Yes in step S405). Accordingly, a value of Value [5] corresponding to Key [5] is read from address 4 of the second memory 102, which is an address indicated by a pointer value stored at address 6 of the pointer region 112 of the first memory 101 (step S408). Thereafter, this process ends.

E-4. Value Writing by Key Search

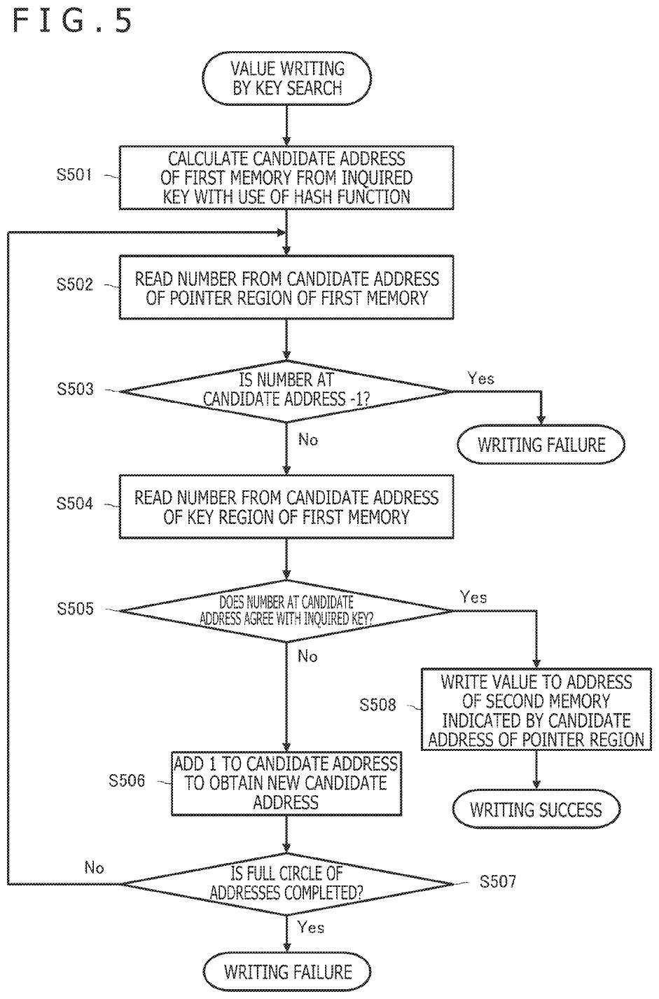

FIG. 5 presents a processing procedure for value writing based on key search performed by the storage apparatus 100, in a form of a flowchart.

First, a key corresponding to a value intended to be written is input to the mapping unit 104, and a candidate address of the first memory 101 is calculated using an ordinary hash function (step S501).

Next, a number is read from the candidate address of the pointer region 112 of the first memory 101 (step S502). Thereafter, it is checked whether or not the number read from the candidate address in step S502 is −1, i.e., whether or not the corresponding candidate address is unused (step S503).

When the number read from the candidate address is −1 here (Yes in step S503), it is considered that the corresponding address is unused and that the value is yet to be registered for the corresponding key. Accordingly, this process ends considering that value writing based on key search has failed.

On the other hand, when the number read from the candidate address is not −1 (No in step S503), the candidate address is already used. Accordingly, an address matching the searched key is searched in the key region 111.

As a process for search in the key region 111, a number is first read from a candidate address of the key region 111 of the first memory 101 (step S504). Then, it is checked whether or not the number read from the candidate address of the key region 111 of the first memory 101 agrees with the number input in step S501 as the key corresponding to the value intended to be written (step S505).

Here, in a case where the number read from the candidate address of the key region 111 agrees with the key corresponding to the value intended to be written (Yes in step S505), it is considered that the key has been registered at the candidate address calculated from the key with use of the hash function. Accordingly, a pointer value stored at the corresponding candidate address of the pointer region 112 of the first memory 101 is read out. Thereafter, a value is written to the address indicated by the pointer value in the second memory 102 (step S508), and this process ends.

On the other hand, in a case where the number read from the candidate address of the key region 111 does not agree with the key corresponding to the value intended to be read (No in step S505), it is considered that a hash collision has been caused. Accordingly, the collision is avoided using the open addressing method. Specifically, the candidate address calculated in step S501 is incremented by only one to obtain a new candidate address (step S506).

It is checked here whether or not the new candidate address has turned full circle of the addresses in the first memory 101 (step S507). When full circle is not completed (No in step S507), the process returns to step S502 to check again whether or not the corresponding key has been stored at the new candidate address.

On the other hand, in a case where full circle of the addresses in the first memory 101 is completed (Yes in step S507), it is considered that an address matching the inquired key is absent and that the value is yet to be registered for the corresponding key. Accordingly, this process ends considering that value writing based on key search has failed.

For example, in a case where the storage apparatus 100 performs value writing based on search for a key of Key [1] in a state where keys and values have already been registered as depicted in FIG. 1, the mapping unit 104 first calculates a hash value “5” of Key [1] as a candidate address by using the hash function (step S501). The number read from address 5 of the pointer region 112 of the first memory 101 is not −1 (No in step S502 and step S503), and thus, a number is next read from address 5 of the key region 111 of the first memory 101 (step S504). This number agrees with the searched key of Key [1] (Yes in step S505). Accordingly, a value of Value [1] corresponding to Key [1] is written to address 0 of the second memory 102, which is indicated by a pointer value stored at address 5 of the pointer region 112 of the first memory 101 (step S508). Thereafter, this process ends. Values of Value [2], Value [3], and Value [4] corresponding to keys of Key [2], Key [3], and Key [4], respectively, can be written by a similar value writing processing flow based on key search.

On the other hand, in a case of value writing based on search for a key of Key [5], the mapping unit 104 first calculates a hash value “5” of Key [5] as a candidate address by using the hash function (step S501). The number read from address 5 of the pointer region 112 of the first memory 101 is not −1 (No in step S502 and step S503), and thus, a number is next read from address 5 of the key region 111 of the first memory 101 (step S504). This number does not agree with the searched key of Key [5] (No in step S505). In other words, a hash collision is caused, and thus, the collision is avoided using the open addressing method. Specifically, the candidate address is incremented by only one to obtain address 6 (step S506). Full circle of the addresses in the first memory 101 is yet to be completed (No in step S507), and thus, the flow returns to step S502 to repeatedly perform key search at address 6. Thereafter, a number is subsequently read from address 6 of the key region 111 (step S504). This number agrees with the searched key of Key [5] (Yes in step S505). Accordingly, a value of Value [5] corresponding to Key [5] is written to address 4 of the second memory 102, which is an address indicated by a pointer value stored at address 6 of the pointer region 112 of the first memory 101 (step S508). Thereafter, this process ends.

E-5. New Key and Value Writing

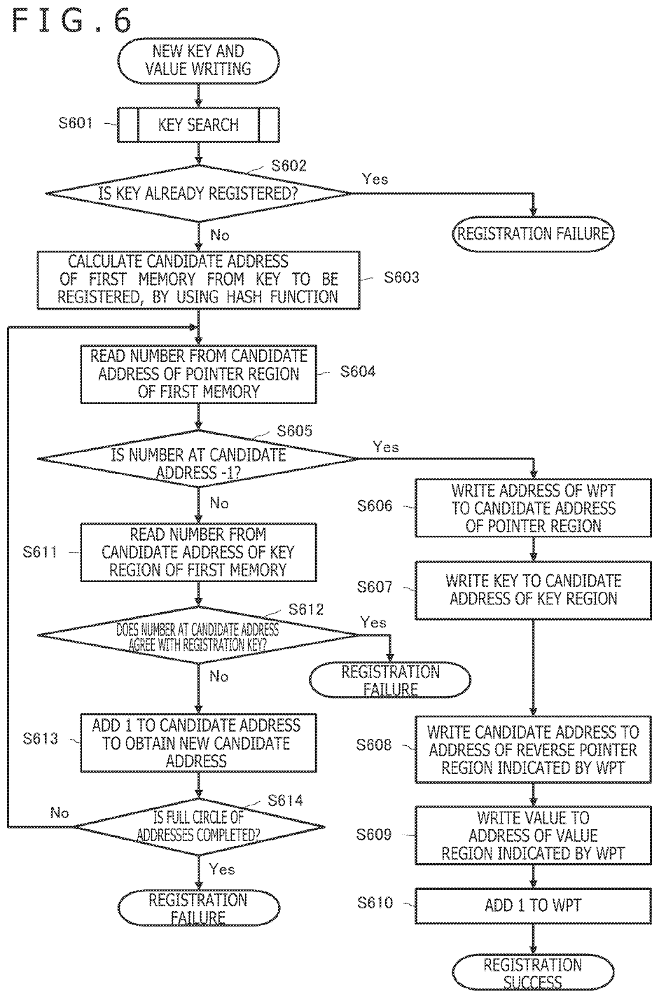

FIG. 6 presents a processing procedure for new key and value writing performed by the storage apparatus 100, in a form of a flowchart.

First, a key to be registered is searched according to the processing procedure presented in FIG. 3 (step S601). In a case where the inquired key is determined to have already been registered in the storage apparatus 100 (Yes in step S602), this process ends considering that registration of the key and the value has failed.

In a case where the inquired key is yet to be registered in the storage apparatus 100 (No in step S602), the key to be registered is input to the mapping unit 104, and a candidate address of the first memory 101 is calculated using an ordinary hash function (step S603).

Next, a number is read from the candidate address of the pointer region 112 of the first memory 101 (step S604). Thereafter, it is checked whether or not the number read from the candidate address in step S604 is −1, i.e., whether or not the corresponding candidate address is unused (step S605).

Here, when the number read from the candidate address is −1, i.e., when the candidate address is unused (Yes in step S605), the key and the value are newly written to this unused address.

In the new key and value writing process, an address of the writing pointer 105 is first written to the corresponding candidate address of the pointer region 112 of the first memory 101 (step S606), and the key to be registered is written to the corresponding candidate address of the key region 111 (step S607).

Subsequently, the corresponding candidate address is newly written to an address indicated by the writing pointer 105 in the reverse pointer region 131 of the third memory 103 (step S608), and then the value is newly written to the address indicated by the writing pointer 105 in the value region 121 of the second memory 102 (step S609).

Thereafter, the writing pointer 105 is incremented by only one (step S601) to indicate an address of next writing. Then, this process ends considering that new key and value writing has succeeded.

On the other hand, when the number read from the candidate address is not −1 (No in step S605), the candidate address is already used. Accordingly, an unused address is searched in the key region 111.

As a process for searching an unused address in the key region 111, a number is first read from a candidate address of the key region 111 of the first memory 101 (step S611). Next, it is checked whether or not the number read from the candidate address of the key region 111 of the first memory 101 agrees with the key to be registered (step S612).

Here, in a case where the number read from the candidate address of the key region 111 agrees with the key to be registered (Yes in step S612), it is considered that the key has already been registered at the candidate address calculated from the key with use of the hash function. Accordingly, this process ends considering that new writing of the key and the value has failed.

On the other hand, in a case where the number read from the candidate address of the key region 111 does not agree with the key to be registered (No in step S612), it is considered that a hash collision has been caused. Accordingly, the collision is avoided using the open addressing method. Specifically, the candidate address calculated in step S603 is incremented by only one to obtain a new candidate address (step S613).

It is checked here whether or not the new candidate address has turned full circle of the addresses in the first memory 101 (step S614). When full circle is not completed (No in step S614), the process returns to step S604 to check again whether or not the key and the value can be newly written to the new candidate address.

On the other hand, in a case where full circle of the addresses in the first memory 101 is completed (Yes in step S614), it is considered that an address matching the inquired key is absent and that the value is yet to be registered for the key. Accordingly, this process ends considering that new writing of the key and the value has failed.

For example, in a case where new key and value writing is performed in an order of Key [1], Key [2], Key [3], Key [4], and Key [5] in a state where the storage apparatus 100 depicted in FIG. 1 has been initialized, each of candidate addresses in the pointer region 112, which are addresses indicated by hash values calculated by the mapping unit 104 on the basis of the respective keys with use of the hush function, has a number of −1, i.e., each of the candidate addresses is unused for Key [1], Key [2], Key [3], and Key [4]. Accordingly, the flow proceeds to Yes at a branch in step S605, and sequentially performs respective processes of writing of the address of the writing pointer 105 to the candidate address of the pointer region 112 (step S607), new writing of the key to the candidate address of the key region 111 (step S608), writing of the candidate address to the address indicated by the writing pointer 105 in the reverse pointer region 131 (step S609), and new writing of the values corresponding to the respective keys to the address indicated by the writing pointer 105 in the value region 121 (step S610).

On the other hand, concerning new key and value writing of Key [5], the candidate address of the pointer region 112 which is an address indicated by the hash value calculated from the key of Key [5] using the hash function has already been used, and it is considered that a hash collision has been caused. In this case, the collision is avoided using the open addressing method. In other words, the flow proceeds to No at a branch of step S605 to perform a search process for searching an unused address in the key region 111. Specifically, the candidate address is incremented by only one to obtain address 6 (step S613). Full circle of the addresses in the first memory 101 is yet to be completed (No in step S614), and thus, the flow returns to step S604 to repeatedly perform new key and value writing at address 6. In this case, address 6 in the key region 111 has a number of −1, i.e., address 6 is unused. Accordingly, the flow proceeds to Yes at a branch in step S605, writes address 4 retained by the writing pointer 105 to address 6 of the pointer region 112 (step S606), newly writes a key of Key [5] to address 6 of the key region 111 (step S607), writes “6” indicating a candidate address of the key region 111 to address 5 indicated by the writing pointer 105 in the reverse pointer region 131 (step S609), and writes a value of Value [5] corresponding to a key of Key [5] to address 5 indicated by the writing pointer 105 in the value region 121 (step S610).

E-6. Sequential All Key and Value Reading

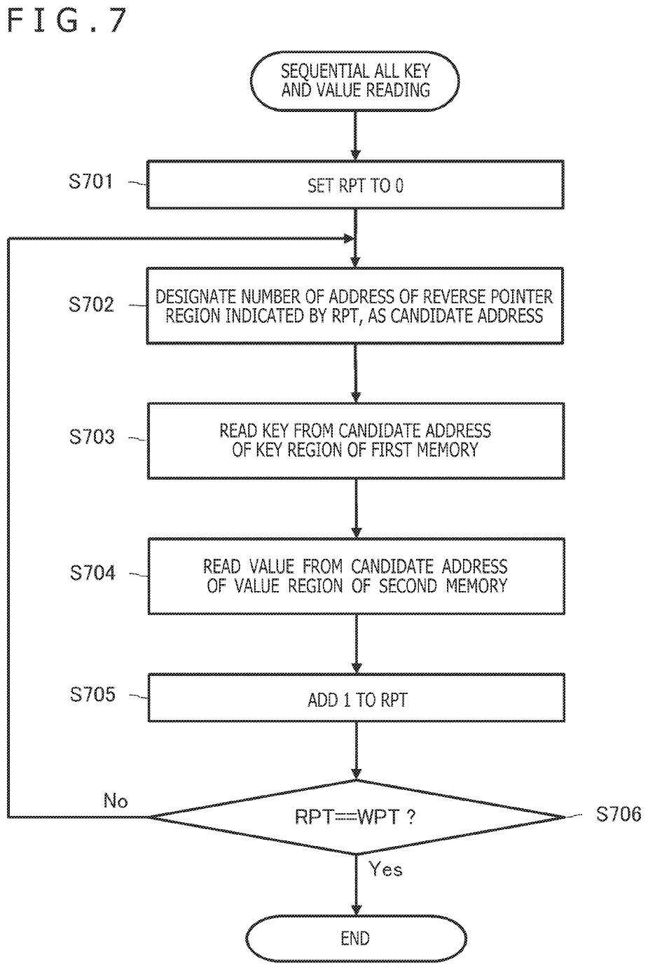

FIG. 7 presents a processing procedure for sequential all key and value reading performed by the storage apparatus 100, in a form of a flowchart.

First, the reading pointer 106 is set to 0 (step S701).

Next, a number stored at an address indicated by the reading pointer 106 in the reverse pointer region 131 of the third memory 103 is designated as a candidate address (step S702). Thereafter, a key stored at a candidate address of the key region 111 of the first memory 101 is read out (step S703).

Then, a value corresponding to the key read in preceding step S703 is read from an address indicated by the reading pointer 106 in the value region 121 of the second memory 102 (step S704).

Thereafter, the reading pointer 106 is incremented by only one (step S705), and the abovementioned processing from S702 to S705 is repeated until the number of the reading pointer 106 agrees with the number of the writing pointer 105 (No in step S706). In this manner, all keys and values can be sequentially read out.

For example, in a case where the storage apparatus 100 performs sequential all key and value reading in a state where keys and values have already been registered as depicted in FIG. 1, the reading pointer 106 is set to 0 (step S701). A number (“5”) stored at address 0 of the reverse pointer 131 of the third memory 103, i.e., address 5, is first designated as a candidate address (step S702). Then, a key of Key [1] at address 5 of the key region 111 of the first memory 101 is read out (step S703), and a value of Value [1] stored at address 0 of the value region 121 of the second memory 102 is read out (step S704).

Thereafter, the processing from step S702 to step S704 is repeated along with incrementation of the reading pointer 106 one by one (step S705). In this manner, Key [2] and Value [2], Key [3] and Value [3], Key [4] and Value [4], and Key [5] and Value [5] can be sequentially read out. When the number of the reading pointer 106 agrees with the number “5” of the writing pointer 105 (Yes in step S706), reading of all keys and values is considered to be completed. Accordingly, this process ends.

E-7. Sequential All Key and Value Reading and Value Update

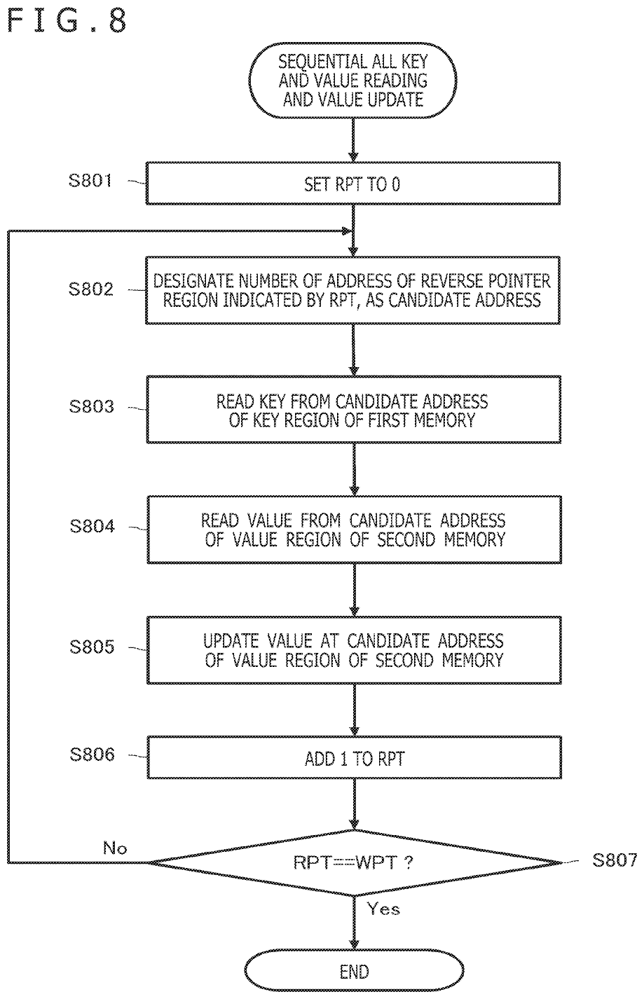

FIG. 8 presents a processing procedure for sequential all key and value reading and value update performed by the storage apparatus 100 in a form of a flowchart.

First, the reading pointer 106 is set to 0 (step S801).

Next, a number stored at an address indicated by the reading pointer 106 in the reverse pointer region 131 of the third memory 103 is designated as a candidate address (step S802). Thereafter, a key stored at a candidate address of the key region 111 of the first memory 101 is read out (step S803).

Then, a value corresponding to the key read in the preceding step S803 is read from an address indicated by the reading pointer 106 in the value region 121 of the second memory 102 (step S804).

Subsequently, the value at the address indicated by the reading pointer 106 in the value region 121 is updated (step S805).

Thereafter, the reading pointer 106 is incremented by only one (step S806), and the abovementioned processing from S802 to S806 is repeated until the number of the reading pointer 106 agrees with the number of the writing pointer 105 (No in step S807). In this manner, all keys and values can be sequentially read out, and the values are updated.

For example, in a case where the storage apparatus 100 performs sequential all key and value reading and value update in a state where keys and values have already been registered as depicted in FIG. 1, the reading pointer 106 is set to 0 (step S801). A number (“5”) stored at address 0 of the reverse pointer 131 of the third memory 103, i.e., address 5, is first designated as a candidate address (step S802). Then, a key of Key [1] at address 5 of the key region 111 of the first memory 101 is read out (step S803), and a value of Value [1] stored at address 0 of the value region 121 of the second memory 102 is read out (step S804). Thereafter, the value of Value [1] at that address is updated (step S805).

Subsequently, the processing from step S802 to step S805 is repeated along with incrementation of the reading pointer 106 one by one (step S806). In this manner, Key [2] and Value [2], Key [3] and Value [3], Key [4] and Value [4], and Key [5] and Value [5] can be sequentially read out. When the number of the reading pointer 106 agrees with the number “5” of the writing pointer 105 (Yes in step S807), sequential reading of all keys and values and update of the values are considered to be completed. Accordingly, this process ends.

### F. Implementation Example

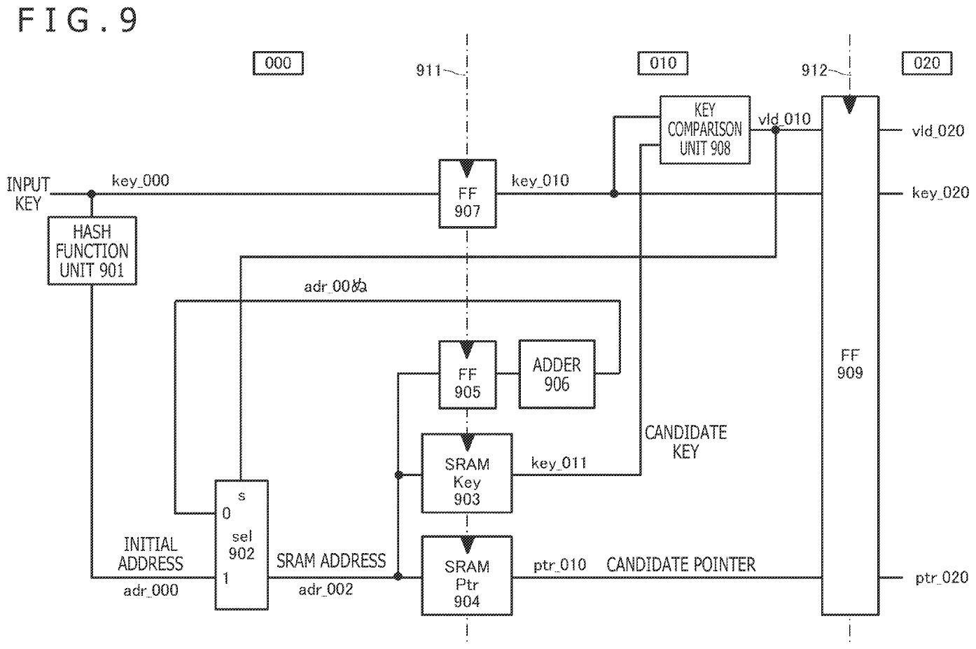

FIG. 9 depicts an example of a pipeline circuit 900 where contents of the processing procedures performed during key search as presented in FIG. 3 are implemented using a clocked SRAM.

A key of key_000 is input to each clock in the pipeline circuit 900.

A hash function unit 901, which corresponds to the mapping unit 104 in the storage apparatus 100 depicted in FIG. 1, calculates a hash value of an input key of key_000, and outputs the hash value as a candidate address (initial address) adr_000.

When receiving inputs of the initial address adr_000 and an address adr_001 output from an adder 6 described below, a selector (sel) 902 alternatively outputs any one of the two pieces of input data, i.e., adr_000 or adr_001, as a candidate address (SRAM address) adr_002 for the pointer region 112, according to a key comparison result vld_010 output from a key comparison unit 908 described below as a select input.

An SRAM Key unit 903 corresponds to a first memory 101 (key region 111) including an SRAM in the storage apparatus 100 depicted in FIG. 1, and outputs a key of key_011 stored at the candidate address adr_002 selected by the selector 902, as a candidate key, after an elapse of one clock.

An SRAM Ptr unit 904 corresponds to the pointer region 112, and outputs a pointer value ptr_010 stored at the candidate address adr002 selected by the selector 902, after an elapse of one clock. The pointer value ptr_010 is a candidate address where the value corresponding to the key is stored in the second memory 102.

A flipflop (FF) 905 retains the candidate address (SRAM address) adr002 input for each clock, for only one clock, and outputs the candidate address adr002 with a delay. Note that one-dot chain lines indicated by reference numbers 911 and 912 in FIG. 9 each represent clock switching.

An adder 906 adds only one to the candidate address (SRAM address) adr_002 output from the flipflop 905 with the only one clock delay, and outputs the resultant candidate address adr_002 to the selector (sel) 902.

A flipflop 907 retains the key of key_000 input for each clock, for only one clock, and outputs the key of key_000 as an input key of key_010, with a delay.

A key comparison unit 908 compares the key of key_010 input from the flipflop 907 one clock before and a candidate key of key_011 input from the SRAM Key unit 903, and outputs 1 in a case of agreement between these keys and 0 in a case of disagreement between these keys, as vld_010 indicating validity of the candidate key.

The selector (sel) 902 described above outputs the initial address adr_000 as a candidate address adr_002 when the select input vld_010 is 1 (i.e., when the input key of key_010 and the candidate key of key_011 agree with each other). In addition, the selector (sel) 902 outputs the candidate address adr_001 obtained by adding one to the candidate address one clock before, as the candidate address adr_002, when the select input vld_010 is 1 (i.e., when the input key of key_010 and the candidate key of key_011 do not agree with each other).

Accordingly, in a case of agreement between the candidate key of key_011 stored at the candidate address adr002 of the SRAM Key unit 903 and the input key of key_010, the SRAM Ptr unit 904 outputs, as a candidate pointer, a pointer value stored at the candidate address (initial address) adr_000 as the hash value of the input key of key_000. On the other hand, in a case of disagreement, it is assumed that a hash collision has been caused. In this case, a pointer value stored at the candidate address adr_001 obtained by adding only one to the candidate address (initial address) adr_000 is output as a candidate pointer.

A flipflop 909 in the following stage outputs, with a further delay of only one clock, each of the comparison result vld_010 obtained by the key comparison unit 908, as vld_020, the key of key_010 output from the flipflop 907, as a candidate key of key_020, and ptr_010 output from the SRAM Ptr unit 904, as a candidate pointer ptr20.

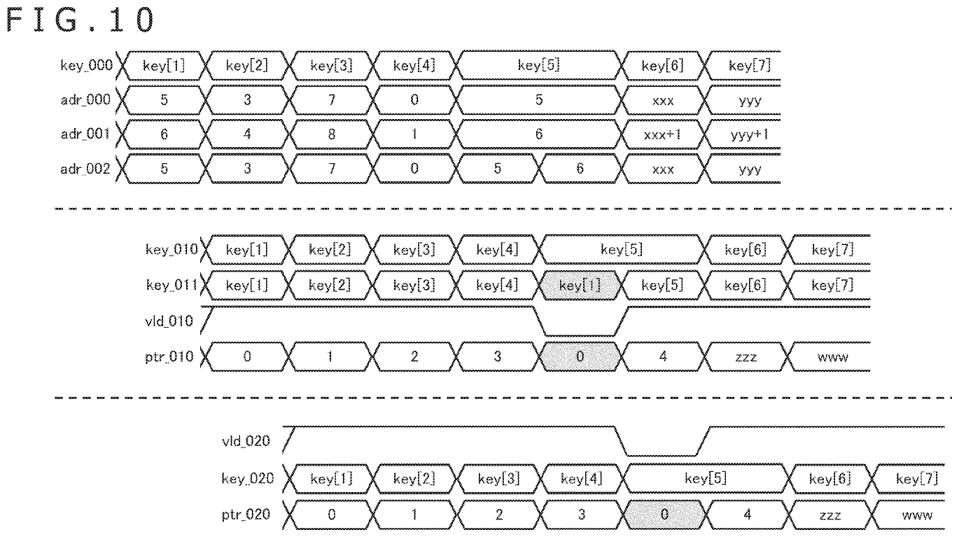

FIG. 10 presents a timing chart of the pipeline circuit 900 depicted in FIG. 9 in a case where key search is performed in an order of Key [1], Key [2], Key [3], Key [4], Key [5], Key [6], and Key [7].

When key [1] is input as an input key at an initial clock, the initial address adr_000 as a hash value of this input is “5.” In this case, the address adr_001 obtained by adding only one to the initial address is “6.” In addition, a select input to the selector 902 is a high signal. Accordingly, an SRAM address selected by the selector 902 becomes initial address adr_000 “5.”

With a delay of only one clock, the flipflop 907 outputs an input key of Key [1], and the SRAM Key unit 903 outputs a candidate key of Key [1] stored at SRAM address “5.” The input key of key_010 and the candidate key of key_011 agree with each other. Accordingly, the key comparison unit 908 outputs a high signal as vld_010, and the SRAM Ptr unit 904 outputs address “0” as a candidate pointer of ptr_010 stored at SRAM address “5.”

With a further delay of only one clock, the flipflop 909 outputs Key [1] as a key of key_020 and address “0” as a pointer value of ptr_020, and also outputs a high signal as vld020 indicating validity of these key and pointer value.

Next, when key [2] is input as an input key, the initial address adr_000 as a hash value of this input is “3.” In this case, the address adr_001 obtained by adding only one to the initial address is “4,” and the SRAM address selected by the selector 902 is “3.” In this case, the input key of key_010 and the candidate key of key_011 also agree with each other. Accordingly, the key comparison unit 908 outputs a high signal as vld_010, and the SRAM Ptr unit 904 outputs address “1” as a candidate pointer of ptr_010 stored at SRAM address “3,” with a delay of only one clock. With a further delay of only one clock, the flipflop 909 outputs Key [2] as a key of key_020, and address “1” as a pointer value of ptr_020, and also outputs a high signal as vld020 indicating validity of these key and pointer value.

Then, when key [3] is input as an input key, the initial address adr_000 as a hash value of this input is “7.” In this case, the address adr_001 obtained by adding only one to the initial address is “8,” and the SRAM address selected by the selector 902 is “3.” In this case, the input key of key_010 and the candidate key of key_011 also agree with each other. Accordingly, the key comparison unit 908 outputs a high signal as vld_010, and the SRAM Ptr unit 904 outputs address “2” as a candidate pointer of ptr_010 stored at SRAM address “7,” with a delay of only one clock. With a further delay of only one clock, the flipflop 909 outputs Key [3] as a key of key_020 and address “2” as a pointer value of ptr_020, and also outputs a high signal as v1d020 indicating validity of these key and pointer value.

Following this, when key [4] is input as an input key, the initial address adr_000 as a hash value of this input is “3.” In this case, the address adr_001 obtained by adding only one to the initial address is “0,” and the SRAM address selected by the selector 902 is “1.” In this case, the input key of key_010 and the candidate key of key_011 also agree with each other. Accordingly, the key comparison unit 908 outputs a high signal as vld_010, and the SRAM Ptr unit 904 outputs address “3” as a candidate pointer of ptr_010 stored at SRAM address “0,” with a delay of only one clock. With a further delay of only one clock, the flipflop 909 outputs Key [4] as a key of key_020 and address “3” as a pointer value of ptr_020, and also outputs a high signal as v1d020 indicating validity of these key and pointer value.

Subsequently, when key [5] is input as an input key, the initial address adr_000 as a hash value of this input is “5.” In addition, the address adr_001 obtained by adding only one to the initial address is “6,” and the SRAM address selected by the selector 902 is “5.” In this case, the input key of key_010 and the candidate key of key_011 do not agree with each other. In other words, a hash collision is caused. This collision is thus avoided using the open addressing method.

Specifically, the key comparison unit 908 outputs a low signal as vld_010, and the SRAM Ptr unit 904 outputs address “0” as a candidate pointer of ptr_010 stored at SRAM address “5,” with a delay of only one clock. Moreover, in response to input of the low signal to a select input s, the selector 902 outputs “6,” which is an address of adr_001 obtained by adding one to the initial address, as an SRAM address of adr_002.

Thereafter, at a subsequent clock, the SRAM Key unit 903 outputs a candidate key of Key [5] stored at the SRAM address “6.” In this case, the input key of key_010 and the candidate key of key_011 agree with each other. Accordingly, the key comparison unit 908 outputs a high signal as vld_010, and the SRAM Ptr unit 904 outputs address “4” as a candidate pointer of ptr_010 stored at SRAM address “5.”

With a further delay of only one clock, the flipflop 909 outputs Key [5] as a key of key_020 and address “4” as a pointer value of ptr_020, and also outputs a high signal as vld_020 indicating validity of these key and pointer value.

### G. Advantageous Effect

Finally mentioned will be advantageous effects of the storage apparatus 100 of an associative array type according to the present embodiment.

In a case where the HDGF technology is applied to a stereo depth calculation process, a large-sized cost volume is recorded in value data of an associative array (as described above). Specifically, one key has a size of 60 bits. However, one value (cost vector) has a large size of several kilobits, and a cost volume becomes as large as 236 megabytes. Accordingly, in a case where a pair of a key and a value is simply handled in the associative array system, a memory capacity for values increases by an increase in an address space. In this case, a capacity waste increases considerably. On the other hand, according to the hardware configuration of the storage apparatus 100 of the associative array type depicted in FIG. 1, a value is associated with a key by a pointer, but is stored in the storage region including a DRAM that is different from a storage region including an SRAM for keys. Accordingly, this configuration requires costs for pointers and the like, but eliminates a waste of the storage capacity for values. In addition, this configuration can offer such an advantageous effect that a large volume of values are stored at low cost.

Moreover, according to the hardware configuration of the storage apparatus 100 of the associative array type depicted in FIG. 1, re-reference address for the first memory 101 at the time of a collision can be calculated by the open addressing method beforehand. Accordingly, latency retained by a clocked SRAM can be concealed, and throughput can be kept at one as long as no collision is caused. Further offered is such an advantageous effect that a clock loss produced as a result of a collision is reduced to only the number of times of occurrence×1.

### INDUSTRIAL APPLICABILITY

The technology disclosed in the present description has been described in detail with reference to the specific embodiment. However, it is obvious that corrections or replacements can be made for the embodiment by those skilled in the art without departing from the scope of the subject matters of the technology disclosed in the present description.

For example, the storage apparatus of the associative array type disclosed in the present description is applicable to an HDGF circuit which performs image processing such as noise removal and semantic segmentation for a two-dimensional image or a three-dimensional CT image, for example. Moreover, a stereo depth calculation circuit may be constituted by use of the HDGF circuit to which the storage apparatus of the associative array type disclosed in the present description is applied.

The storage apparatus disclosed in the present description is applicable to various types of information processing apparatuses using the associative array system. The storage apparatus disclosed in the present description is suited for an information processing apparatus which requires a large address space and has a use application of handling values in a large data size. Specifically, the information processing apparatus may perform image learning, image inference, and the like using an artificial intelligence technology such as deep learning. Moreover, the storage apparatus of the associative array type disclosed in the present description may be a storage apparatus which stores image data used as information input to convolutional neural network or the like.

In short, the technology disclosed in the present description has been described by way of example. Accordingly, it is not intended that the description contents of the present description are interpreted in a limited manner. The appended claims should be referred to for determining the subject matters of the technology disclosed in the present description.

Note that the technology disclosed in the present description may also have the following configurations.

(1)

A storage apparatus of an associative array type including:

a first memory;

a second memory that stores a value; and

a third memory, in which

the first memory stores a key and an address of the second memory, the address of the second memory being an address where the value corresponding to the key is stored, and

the third memory stores an address of the first memory, the address of the first memory being an address where the key corresponding to the value stored in the second memory is stored.

(2)

The storage apparatus according to (1) described above, in which the first memory further stores a flag that indicates whether or not the key has been registered.

(3)

The storage apparatus according to (1) or (2) described above, in which the address at which the key is stored in the first memory is calculated from the key with use of a hash function.

(4)

The storage apparatus according to (3) described above, in which the address at which the key is stored in the first memory is calculated using an open addressing method.

(5)

The storage apparatus according to any one of (1) to (4) described above, in which

each of the first memory and the third memory includes an SRAM, and

a memory of the second memory includes a DRAM.

(6)

An HDGF circuit configured to store a calculation value by using the storage apparatus according to any one of (1) to (5) described above.

(7)

A stereo depth calculation circuit that performs a depth calculation by using the HDGF circuit according to (6) described above.

(8)

An information processing apparatus that stores data by an associative array system with use of the storage apparatus according to any one of (1) to (5) described above.

### REFERENCE SIGNS LIST

100: Storage apparatus

101: First memory

111: Key region

112: Pointer region

102: Second memory

121: Value region

103: Third memory

131: Reverse pointer region

104: Mapping unit

105: Writing pointer

106: Reading pointer

901: Hash function unit

902: Selector

903: SRAM Key unit

904: SRAM Ptr Unit

905: Flipflop

906: Adder

907: Flipflop

908: Key comparison unit

909: Flipflop

1. A storage apparatus of an associative array type comprising:
a first memory;
a second memory that stores a value; and
a third memory, wherein
the first memory stores a key and an address of the second memory, the address of the second memory being an address where the value corresponding to the key is stored, and
the third memory stores an address of the first memory, the address of the first memory being an address where the key corresponding to the value stored in the second memory is stored.

2. The storage apparatus according to claim 1, wherein the first memory further stores a flag that indicates whether or not the key has been registered.

3. The storage apparatus according to claim 1, wherein the address at which the key is stored in the first memory is calculated from the key with use of a hash function.

4. The storage apparatus according to claim 3, wherein the address at which the key is stored in the first memory is calculated using an open addressing method.

5. The storage apparatus according to claim 1, wherein
each of the first memory and the third memory includes an SRAM, and
a memory of the second memory includes a DRAM.

6. A High Dimensional Gaussian Filtering (HDGF) circuit configured to store a calculation value by using the storage apparatus according to claim 1.

7. A stereo depth calculation circuit that performs a depth calculation by using the HDGF circuit according to claim 6.

8. An information processing apparatus that stores data by an associative array system with use of the storage apparatus according to claim 1.
